(19) United States
(12) Patent Application Publication
(10) Pub. No.: US 2008/0245930 A1
(43) Pub. Date: Oct. 9, 2008

(54) HIGH INTENSITY LASER POWER BEAMING RECEIVER FOR SPACE AND TERRESTRIAL APPLICATIONS

(76) Inventors: Taysir H. Nayfeh, Cleveland, OH (US); Brian R. Fast, Baltimore, OH (US); Daniel Raible, Westlake, OH (US); Nick Tollis, Parma, OH (US); Andrew Jalics, Akron, OH (US); Dragos Dinca, Cleveland, OH (US)

Correspondence Address: FAY SHARPE LLP, 1100 SUPERIOR AVENUE, SEVENTH FLOOR, CLEVELAND, OH, 44114, US

(21) Appl. No.: 11/968,863

(22) Filed: Jan. 3, 2008

Related U.S. Application Data
(60) Provisional application No. 60/878,605, filed on Jan. 4, 2007.

(51) Int. Cl. H01S 3/00; B64D 39/00; B64D 33/00

(52) U.S. Cl. 244/53 R; 244/135 A

(57) ABSTRACT

Systems and methods are described that facilitate refueling a vehicle with electrical energy by targeting receiver thereon and pointing a high-intensity laser source at the receiver. Vertical multi-junction (VMJ) photocells receive the laser energy and convert the laser energy into electrical energy. The laser source can operate at a range of output power levels depending on the vehicle's energy needs. The laser source can be pulsed or continuous near-infrared laser source. A heat exchanger can be coupled to the receiver to dissipate laser energy not converted into electrical energy. If the vehicle has a propeller, the heat exchanger can be mounted to the vehicle in the propeller wash path.

This application claims priority to U.S. Provisional Application Ser. No. 60/878,605, entitled HIGH-INTENSITY LASER POWER BEAMING SYSTEM FOR MILITARY AND CIVILIAN APPLICATION, filed on Jan. 4, 2007, the entirety of which is incorporated herein.

The U.S. Government has a paid-up license in this invention and the right in limited circumstances to require the patent owner to license others on reasonable terms as provided for by the terms of Grant No. NCC 3-1081 awarded by NASA-GRC.

### BACKGROUND OF THE INVENTION

This invention relates to a method and apparatus for receiving high-intensity laser light and converting it into electrical energy for refueling a vehicle or a space craft.

While the invention is particularly directed to the art of refueling aerial vehicles, and will be thus described with specific reference thereto, it will be appreciated that the invention has usefulness in other fields and applications.

By way of background, a fundamental problem with modern day combat and surveillance using manned and/or unmanned aircrafts is the onboard fuel capacity. Many compromises are typically made in the design and the payload carrying capacity of aircrafts in order to conserve fuel so that the mission durations can be extended. This drives up design costs dramatically and limits the power plant capacity, thereby seriously reducing maneuverability and limiting mission life, especially in the case of unmanned aerial vehicles (UAVs) such as the Global Hawk and the Predator. Conventional systems do not permit such aircraft to receive fuel as frequently as desired, while in mid-air, from far away platforms to remove the fuel and power limitations currently encountered by UAVs. Such on-demand refueling could reduce aircraft cost dramatically and allow for larger power plants, thereby providing better maneuverability and larger payload carrying capacity, in addition to the ability to stay on target for very long durations.

The present invention contemplates new and improved systems and methods that resolve the above-referenced difficulties and others.

### SUMMARY OF THE INVENTION

Systems and methods for receiving a high-intensity directed laser at a vehicle and converting laser light energy into electrical energy to power the vehicle are provided.

In one aspect, a system that facilitates laser power beaming comprises a receiver mounted to a vehicle and electrically coupled thereto, an array of vertical multi-junction (VMJ) photocells, positioned on the receiver to receive a laser beam, and a global positioning system onboard the vehicle, which transmits location information. The system further comprises a remote position tracking system that receives the location information from the global positioning system, and a high-intensity laser that receives targeting information from the position tracking system, targets the receiver on the vehicle, and provides a laser beam pulse thereto. The VMJ photocells convert at least a portion of the received laser beam energy to electrical energy for use by the vehicle.

In another aspect, a method of mid-air refueling of a vehicle using a near-infrared laser comprises receiving location coordinate information from the vehicle, targeting a receiver on the vehicle with a near-infrared laser source, directing a laser beam form the laser source to a laser-receiving array on the receiver, and receiving the laser beam at one or more vertical multi-junction (VMJ) photocells in the laser-receiving array. The method further comprises converting received laser energy into electrical energy, storing the electrical energy in the VMJ photocells for use by the vehicle, and dissipating heat caused by unconverted laser energy into the ambient atmosphere.

In another aspect, an apparatus for laser power beaming to refuel a vehicle comprises means for receiving a high-intensity laser beam at the vehicle, means for transmitting location information describing the coordinates of the vehicle, means for receiving the location information, and means for aiming the high-intensity laser beam at the vehicle. The apparatus further comprises means for emitting the high-intensity laser beam targeted at the means for receiving the laser beam, means for converting at least a portion of the received high-intensity laser beam energy to electrical energy for use by the vehicle, and means for dissipating heat caused by high-intensity laser beam energy that is not converted into electrical energy.

Further scope of the applicability of the invention will become apparent from the detailed description provided below. It should be understood, however, that the detailed description and specific examples, while indicating preferred embodiments of the invention, are given by way of illustration only, since various changes and modifications within the spirit and scope of the invention will become apparent to those skilled in the art.

### DESCRIPTION OF THE DRAWINGS

The present innovation exists in the construction, arrangement, and combination of the various parts of the device, and steps of the method, whereby the objects contemplated are attained as hereinafter more fully set forth, specifically pointed out in the claims, and illustrated in the accompanying drawings in which:

FIG. 1 illustrates a system that employs high-intensity laser power beaming (HILPB) technology in conjunction with highly energetic photovoltaic cells to transmit large quantities of power wirelessly over large distances.

FIG. 2 shows a photograph of a 40-junction VMJ photovoltaic cell, such as may be employed in conjunction with various aspects described herein.

FIG. 3 is an illustration of the photocell, including an enlarged cut-away portion showing that the photocell employs a P+NN+junction.

FIG. 4 shows exemplary VMJ test results at various solar energy intensities.

FIG. 5 illustrates an exemplary graph showing that the energy conversion efficiency into direct electrical power of the silicon VMJ cells approaches 50%-60% for incident laser light in the 900-980 nm range, and maintains the same linearity for high laser power concentrations as is described above with regard to the solar spectrum.

FIG. 6 illustrates a micro-VMJ photocell, such as may be employed for micro-power beaming systems.

FIG. 7 illustrates an example of the system scaled down for experimental data collection.

FIG. 8 is a graph of the output from the center 5 cells (e.g., arranged in a cross-shaped configuration) of the VMJ array using a 200 W laser beam power.

FIG. 9 illustrates a graph of efficiency vs. temperature for concentrator photocells, such as VMJ photocells.

### DETAILED DESCRIPTION

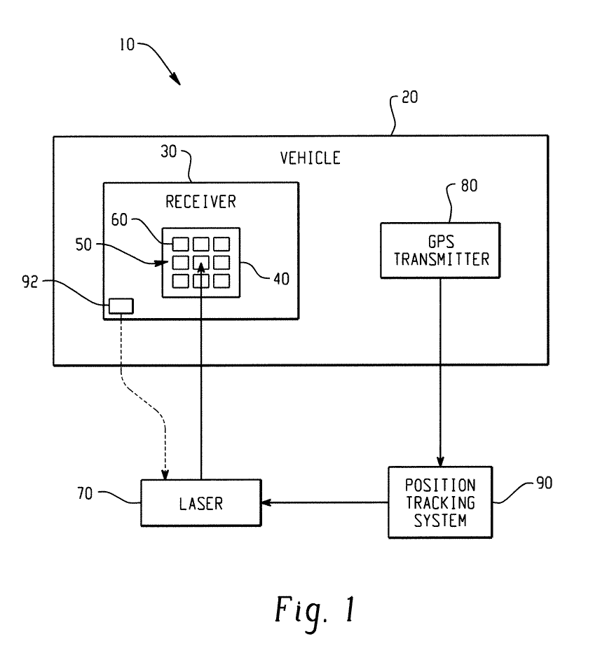

Referring now to the drawings, which are presented for purposes of illustrating various embodiments only and not for purposes of limiting the claimed subject matter, various aspects of the innovation are depicted that relate to a high-intensity laser power receiving system for operations in the atmosphere and/or in space. Additionally, “exemplary,” as used herein, is to be interpreted to mean “an example of.” FIG. 1 illustrates a system 10 that employs high-intensity laser power beaming (HILPB) technology in conjunction with highly energetic photovoltaic cells to transmit large quantities of power wirelessly over large distances. The system 10 includes a vehicle 20, such as an unmanned aerial vehicle (UAV) and miniature UAV (MUAV), with a receiver 30 that optionally includes an aperture 40 for receiving high-intensity laser light. The laser light passes through the aperture and is incident upon a photovoltaic array 50 comprising one or more high-energy photocells 60. In another embodiment, the laser energy is directly incident on the photocells, which are mounted to the surface of the receiver.

The laser beam is emitted from a laser source 70, which may be terrestrially positioned or may be on another vehicle, such as a ship, aircraft, satellite, etc.) It will be appreciated that although the systems and methods described herein refer to UAVs and the like, they are not limited to such and may include manned vehicles, stationary receivers such as may be employed to form a power grid or provide power to remote building(s), terrestrial vehicles (e.g., automobiles or ships, etc.), and other types of platforms on the Moon and/or from satellites on orbit around the Moon and the like.

The system 10 further includes a global positioning system transmitter 80 that transmits coordinate information descriptive of the position of the vehicle 20 to a position tracking system 90, which is coupled to the laser source. The GPS information is used to target the array 50 on the receiver to send a laser light beam to the array 50 to charge the photocells 60.

With regard to the position tracking system, precision targeting capabilities exist and are deployable for space and terrestrial applications. Precision pointing to a cooperative target in the atmosphere with a near-infrared laser is often a simpler task than in the space environment or with non-cooperative targets. The combination of GPS capabilities, infrared lasers in the atmosphere, and a cooperative target is one example of pointing and tracking for power beaming as described herein.

An example of photocells that may be employed in conjunction with various embodiments described herein is PhotoVolt's (Inc.) silicon based “vertical multi-junction” (VMJ) photocells. In this manner, the systems and methods described herein facilitate providing a HILPB receiving (HILPBR) system that is highly efficient and is capable of operating in terrestrial or space environments.

In one embodiment, a HILPBR system for in-air electric power refueling of unmanned aerial vehicles (UAVs) and miniature UAVs (MUAVs) to provide continuous operations over the theater of operations in order to achieve total area domination, among other potential applications. In another embodiment, the laser source(s) 70 are mounted to one or more satellites to compensate for line-of sight issues with regard to targeting the receiver on a vehicle during a refueling protocol.

The HILPBR system 10 is capable of operating continuously at approximately 40-60% optical-to-electrical power conversion efficiency with an optical power input intensity of greater than 50 W/cm² and an electrical output greater than 20 W/cm². The total power reception and conversion capability of the system is a function of available laser power provided by the laser source 70, accuracy of the pointing and tracking system 90, area/mass of a thermal radiator (not shown) for dissipating thermal heat generated by the laser at the receiver 30, etc., which in turn are a function of the allocation of resources and mission requirements for a given mission. In another embodiment, the receiver 30 includes a thermal sensor 92 that sends a shut-off signal to the laser source 70 when the receiver temperature exceeds a predetermined threshold, such as may occur due to excess laser light (e.g., laser light not converted to electrical energy by the cells 60) conversion into thermal energy.

The optional aperture 40 is small relative to the receiver and the vehicle, and the laser source may be a large solid state power laser. Propagation of the laser light can facilitate the formation of a virtual power grid that could potentially deliver power to, from, and between satellites, the moon surface, the earth, etc.

In another embodiment, the system is employed as part of an airborne integrated surveillance and close operations support system, with rapid global reach in all weather conditions. In this embodiment, the system 10 includes constellations of all electric vehicles 20, such as MUAVs and/or manned combat aerial vehicles (MCAVs) that are deployable to a the theater of interest from platforms that include aircraft carriers, airships, etc., and are refuelable in mid-air on location via high intensity lasers 70 stationed far away aboard a multitude of platforms including but not limited to, aircraft carriers, airships, satellites and ground locations in and around the theater of operations. The in-air, long range, laser refueling system facilitates providing continuous and constant area surveillance of the theater of operations by the MUAV and/or MCAV constellations thus forming a low cost, all weather, stable surveillance and combat platforms.

The system 10 is compact and is capable of receiving large amounts of coherent energy at intensities of approximately 250 W/cm² at approximately 50% conversion efficiency. The receiver 30 is also capable of converting highly concentrated sun light at an efficiency of approximately 25% for intensities upwards of 2000 suns, with an air mass (AM) of 1.5, or 250 W/cm². The system's geometry is highly scalable and maintains high efficiency and linearity. In one embodiment, the system 10 is adapted for delivering large amounts of energy to motors, actuators and micro-devices (MEMS) through power beaming with airborne lasers or fiber optics-coupled lasers. When the receiver is mounted on a UAV, excess heat generated in the photocells from the high intensity laser can be dissipated to the atmosphere by placing heat exchanger fins coupled to the receiver behind the propeller wash on the UAV.

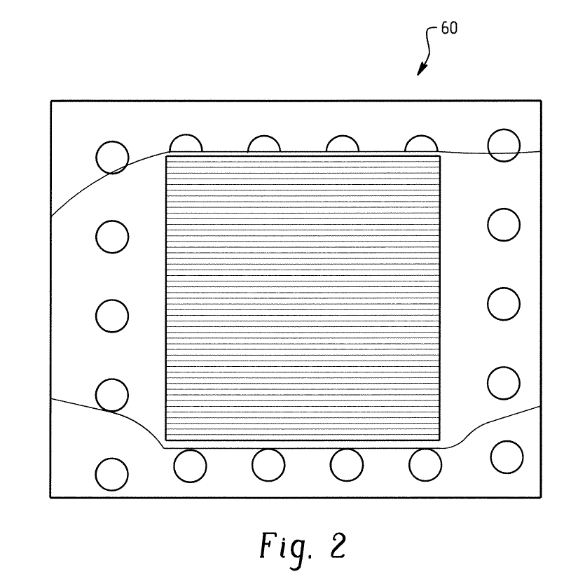

FIG. 2 shows a photograph of a 40-junction VMJ photovoltaic cell 60, such as may be employed in conjunction with various aspects described herein. In one embodiment, the cell may have a surface area of, for instance, 0.8 cm².

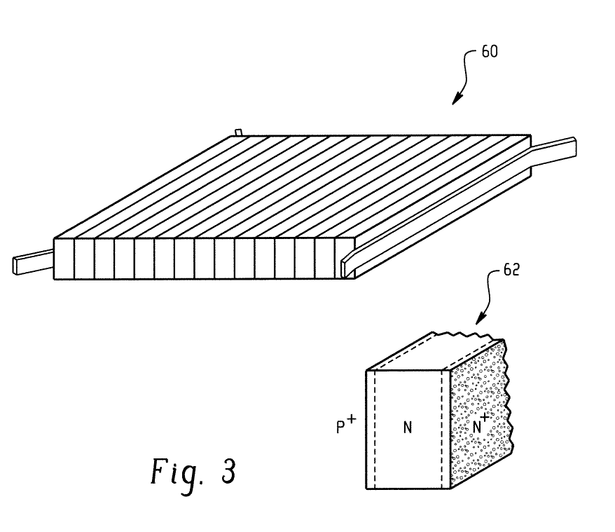

FIG. 3 is an illustration of the photocell 60, including an enlarged cut-away portion showing that the photocell employs a P+NN+junction 62. The photocells may be silicon-based and arranged on edge in a vertical multi-junction (VMJ) format, and are wired in series as needed. In one example, the cells can withstand highly concentrated solar energy while maintaining a conversion efficiency of approximately 25% or better across the full solar spectrum. Remaining concentrated solar energy is converted into thermal energy and/or reflected away. The VMJ cells have undergone numerous tests and operational validation to a solar concentration of 2450 suns at an AM of 1.5, approximately 250 W/cm².

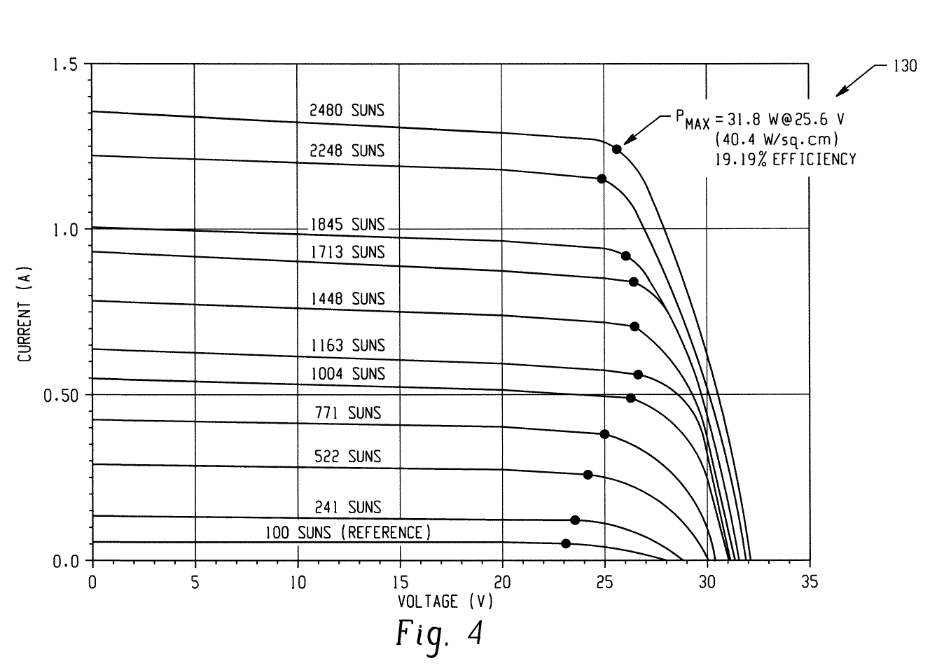

FIG. 4 shows a graph 130 of exemplary VMJ test results at various solar energy intensities. It demonstrates the electrical conversion efficiency of the cells under highly concentrated solar flux equivalent to 2450 suns at an AM of 1.5 (250 W/cm²), resulting in a 40 W/0.8 cm²-sample size at 26.5 volts. The graph shows current-voltage curves for a VMJ cell taken over a range of 100 to 2500 suns, AM 1.5 intensities. The demonstrated conversion efficiency of the VMJ cells is in the 25% range for full spectrum light. This is an average value for all the frequencies (energies) of the solar spectrum. The conversion efficiency increases as the energy of the incident photons decreases and approaches the band gap energy of silicon in the near infrared region of the solar spectrum. The band gap (indirect band gap) for silicon cells ranges from 1.125-1.2 electron volts (ev), depending on its crystalline structure.

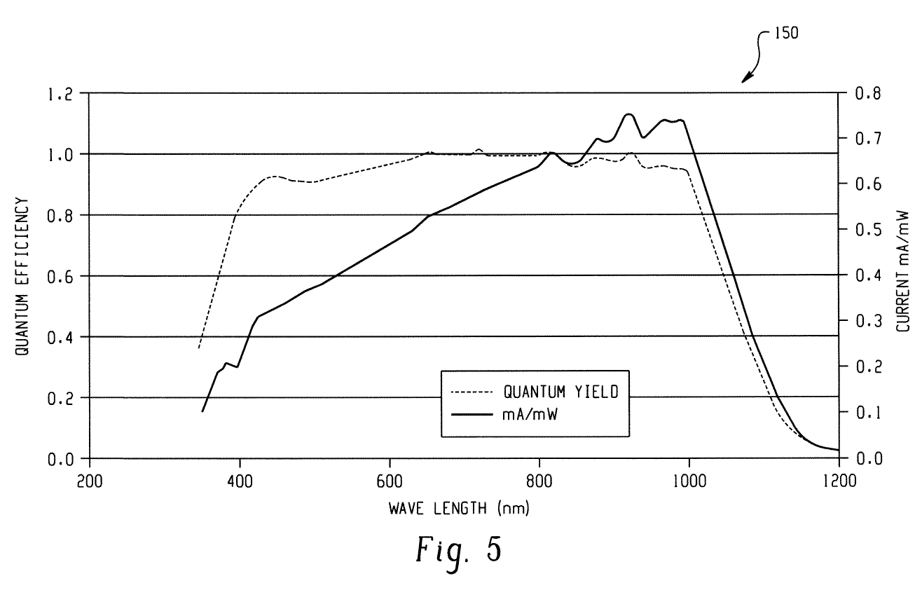

FIG. 5 illustrates an exemplary graph 150 showing that the energy conversion efficiency into direct electrical power of the silicon VMJ cells approaches 50%-60% for incident laser light in the 900-980 nm range, and maintains the same linearity for high laser power concentrations as is described above with regard to the solar spectrum.

The following description relates to the performance of the receiver sub-system unit that receives laser light (e.g., from a 30 kW-100 kW high-intensity near-infrared laser or the like) and converts it into electrons while dissipating excess thermal energy. The performance of the optical power receiving sub-system is a function of several factors including: response of the VMJ cells to Laser light at a given frequency, intensity, and beam uniformity; packing efficiency of the cells on the surface of the receiver; efficiency of the thermal system at rejecting excess heat; efficiency of power electronics in the receiver at maximizing power output and storage; etc.

With regard to cell-level efficiency, experimental results have demonstrated the production of 25 W using a 4 cm² array (5 cells each 0.8 cm² area) of VMJ cells. Although the total incident energy on the surface of the experimental receiver was on the order of 200 W at a frequency of 975 nm, the actual incident energy on the surface of the cells was lower (e.g., on the order of 54 W), yielding an overall conversion efficiency of 44.39%. On a system level, the efficiency is a function of the packing density of the cells on the receiver surface and mismatch between the beam diameter, uniformity, and overfill. The geometric configuration of the VMJ cells relative to space occupied by the electrical connections between cells also affects overall system efficiency.

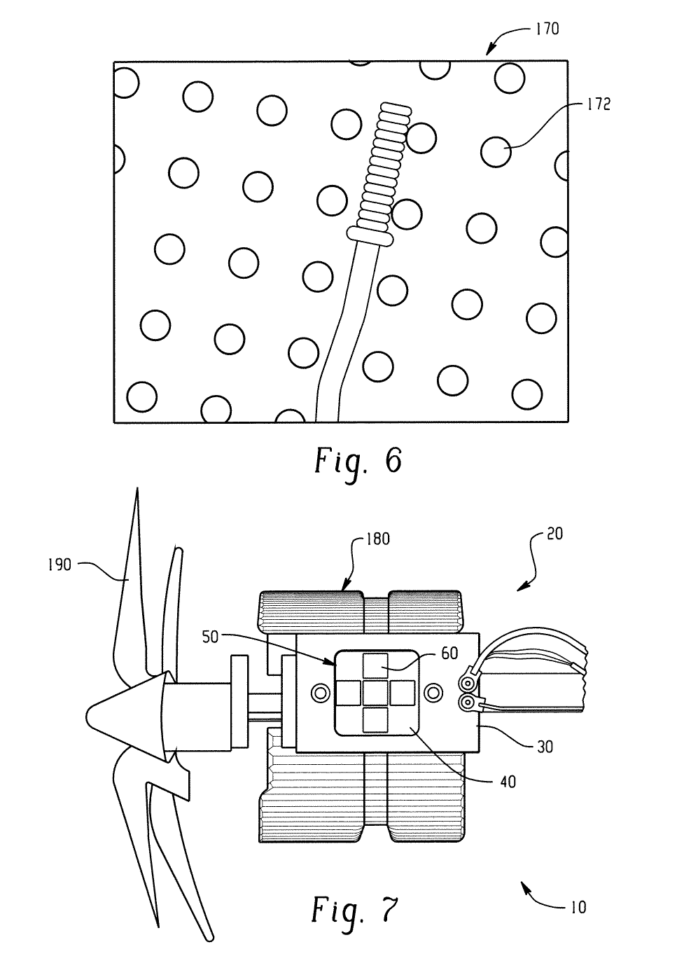

FIG. 6 illustrates a micro-VMJ photocell 170, such as may be employed for micro-power beaming systems. The micro VMJ cell in this example has 9 junctions and 1.2 square millimeters of surface area. The micro-VMJ cell can be employed to supply energy to micro-devices (MEMS), etc., via airborne or fiber optic-coupled lasers.

FIG. 7 illustrates an example of the system 10 scaled down for experimental data collection. As described with regard to FIG. 1, the vehicle 20 is mounted with the receiver 30. The laser light is received by the array 50 of VMJ photocells 60. Laser light that is not converted to electrical energy by the photocells 60 may be converted to thermal energy, which can be dissipated by a heat exchanger 180 with cooling fins. The receiver 30 and heat exchanger 180 are mounted behind the propeller 190 in the path of the propeller wash, in a manner similar to that practiced with piston engine driven airplanes. In another embodiment, the VMJ array is actively cooled.

In one example, a laser with an intensity Of 30 W/cm², and a wavelength of 980 nm is employed. Using standard VMJ cells that are not actively cooled, over 35% conversion efficiency can be achieved. At this laser intensity, approximately 9.36 W can be generated (e.g., 520 mA @18 V DC) from a single VMJ cell with an area of 0.8 cm², thus delivering an equivalent 10.75 W/cm².

Thermal loads as high as 300 W in a VMJ cell area of approximately 25 cm² can be dissipated using a simple microprocessor-style heat exchanger and dissipating the heat to the atmosphere by placing the heat exchanger behind the propeller, in its air wash. Thermocouples embedded in the receiver section above and below the surface of the VMJ cells can maintain the temperature of the cells well below 50° C. with a 300 W thermal load input and a propeller speed of roughly 1000 rpm (slightly bellow the cruising speed of a BatCam MUAV or the like). The 50° C. temperature is well within the optimal operating range for the VMJ cells. Further increases in the speed of the propeller will lower the temperature until reaching a predetermined terminal temperature, such as a design limit of the working fluid inside the heat exchanger pipes.

Efficiency of 50% or better can be reached with further optimization of the VMJ cells and active cooling of the heat exchanger, as is used in one embodiment of the solar concentrator setup. Factors considered in design efficiency include the view factor of the receiver to the laser, laser beam profile and uniformity, beam spread, weather conditions, etc.

The ability of the VMJ cells to absorb and convert huge energy densities at this rate as indicated in Table 1. Significant amounts of energy can be received and converted into electrical power in a very small area of VMJ cells, which facilitates beaming power to UAVs and MUAVs, satellites and micro devices where available real estate is extremely small. The areas shaded in red in the table correspond to high energy densities that may be above the handling capability of the VMJ cells and the corresponding heat exchanger. Exemplary energy densities in the table are shaded in green and blue; however, the blue areas indicate that the array is underpowered and array surface area is being wasted. As can be seen from Table 1, the VMJ cells are able to receive large amounts of energy in a very small surface area. For example, an array of VMJ cells that is 17×17 cm², or approximately 45 in², can generate approximately 7.5 kW of electrical power with a 30 kW laser input at the 25% efficiency level. This power level can easily reach nearly 15 KW by improving the efficiency of the cells and improving the operating practices of the power beaming process. Similarly, 50 kW of electrical power can be realized from a 100 kW laser, with refined power beaming processes.

TABLE 1
Estimation of the power generation capability of VMJ cells @ 25% efficiency vs. array size and laser power

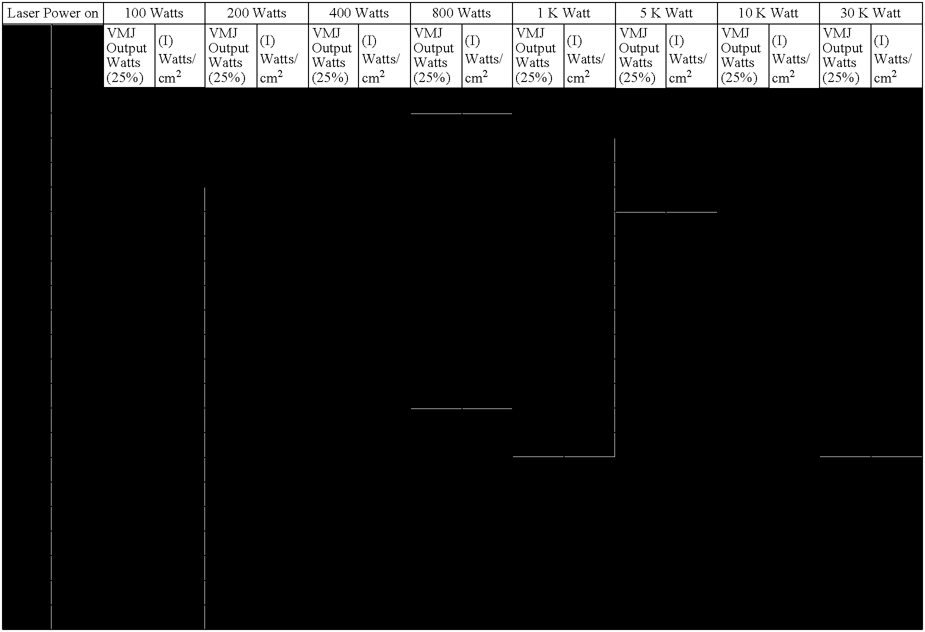

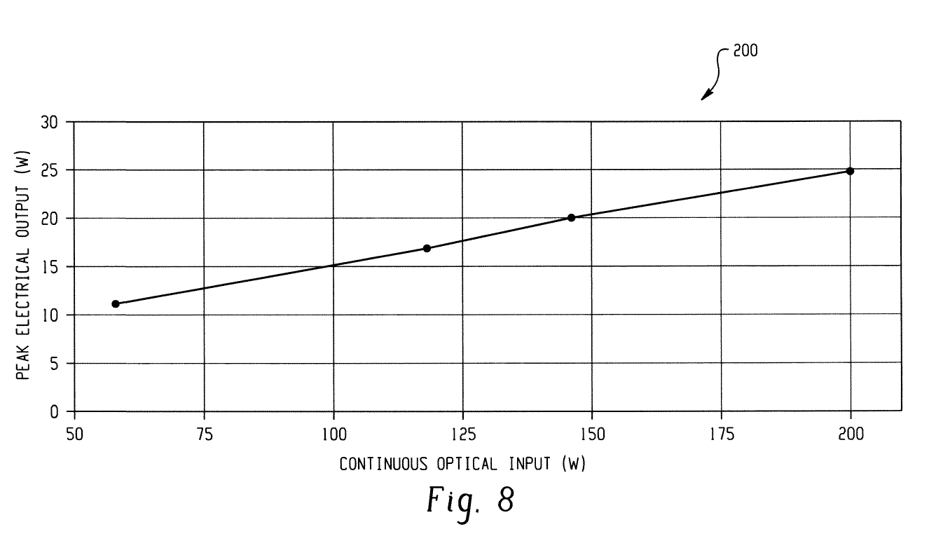

FIG. 8 is graph 200 of the output from the center 5 cells (e.g., arranged in a cross-shaped configuration) of the VMJ array 50 using a 200 W laser beam power. In this example, the receiver area is populated with approximately one half of the possible number of VMJ cells, and the middle 5 cells were fully illuminated. In such an arrangement, one half of the incident optical energy is actually utilized (e.g., 100 W of the full beam power of 200 W). As such, the overall system conversion efficiency achieved in this example is approximately to 25%.

As previously noted, 40%-50% of the impinging laser energy may be converted into heat. Although the VMJ photocells are able to withstand high temperatures of approximately 600°, undesirably large amounts of heat will be generated in a relatively small area. Therefore, it is desirable to consider thermal management in the design and operation of this system in both space and terrestrial applications.

The following discussion of the thermal issues is limited to terrestrial applications of UAVs and airships in moderate to high altitudes in the atmosphere. These applications include high altitude airships and high-flying aircrafts. Heat convection is the dominant mode of heat transfer in the atmosphere and can be highly efficient at dissipating large amounts of energy, especially in the case of aircrafts in flight. Convection is also an efficient method for thermal management in the case of high-altitude air ships hovering or flying at altitudes of 70,000-100,000 ft. Although the air density is low at these altitudes, the wind currents are fairly high and the temperatures are extremely cold. With proper heat exchanger design, large amounts of thermal energy can be efficiently dissipated to maintain a reasonable operating temperature and thus good conversion efficiency of the VMJ cells.

The VMJ cells can withstand the high intensity incident optical energy without damage and/or significant reduction in the conversion efficiency. The combination of the robustness of the silicon based VMJ cells and the efficient thermal management system makes it possible to maintain acceptable temperature levels at the surface of the cells and within the cell structure.

In one embodiment, a plurality of receiver arrays 50 along with a heat exchanger system 180 are exposed to continuous optical energy reaching a maximum of 20 W/cm² without any adverse effects and/or significant reduction in the conversion efficiency. In addition, the system can be exposed to intensities reaching approximately 200 W/cm² for short periods of time without causing any damage.

In another embodiment, the nominal efficiency of the solar cells occurs at 25° C., above which and depending on the type of the semiconductor materials used, the efficiency of conventional “one sun” cells decrease with increases in temperature. This in part is due to the fact that the electric charge carriers (wires) are deposited on the surface and are typically spars in order to avoid masking large portions of the active photovoltaic area of the array. As such, the freed electrons travel relatively long distances (generating heat in the process) before reaching the conduction wires and may recombine with a hole in an electron-hole annihilation process before reaching the conduction wires. This results in the generation of considerable amounts of heat. In addition, further increases in the temperature results in an increase in the vibration level of the free electrons and as such exacerbate the problem and results in further reduction in efficiency. Because of these factors, flat solar array panels are restricted in operation to one sun or approximately 1000 W/m² above which the arrays lose efficiency rapidly and in turn result in a runaway heat generation process which may result in permanent damage.

VMJ cells are designed to operate under extremely high intensity solar energy ranging from 100-2500 suns (10-250 W/cm²). As such, large amounts of heat will be absorbed and/or generated within the individual cells. As was previously mentioned, the efficiency of solar cells degrades with increases in temperature. Therefore, it is desirable that the temperature of the cells be maintained as low as possible, which can be facilitated by transferring substantial amounts of heat out of the cells and into the heat exchanger for rejection.

In some cases, it may be desirable to operate the cells at high temperatures at a reduced efficiency. Catastrophic failures can be avoided by ensuring that the temperature is maintained below the melting point of the electrical contacts and thermal bonding materials, even though silicon and other types of semiconductor materials are rugged and are able to withstand high temperatures (600° C.+).

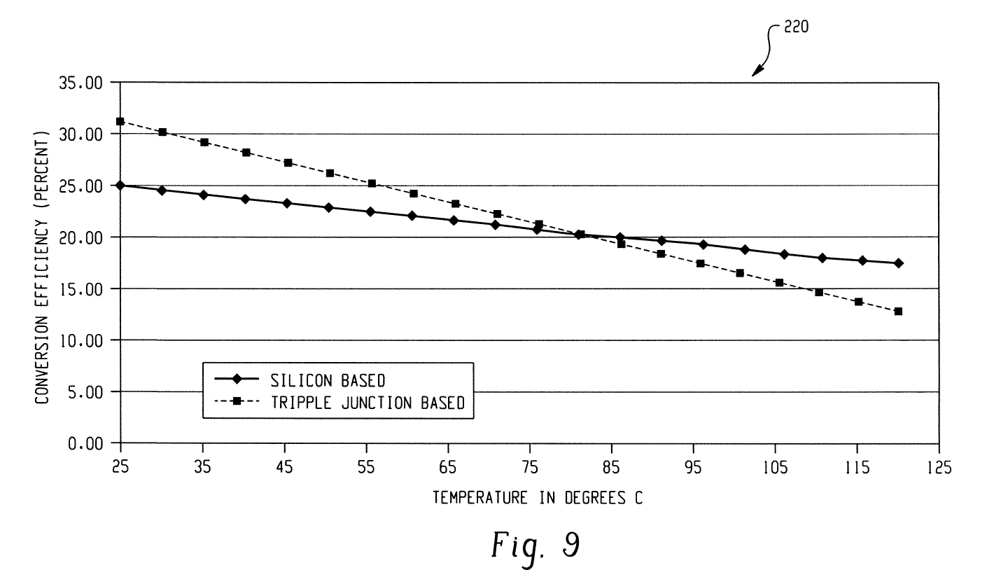

FIG. 9 illustrates a graph 220 of efficiency vs. temperature for concentrator photocells, such as the VMJ photocells 60 described above. Both types of VMJ cells (e.g., silicon and triple junction) are used with several types and brands of solar concentrator systems on the market. Depending on the design and the operating environment of these systems, heat rejection systems may be passive, such as the passive radiators used by the Sol3g company, and/or may be active systems, using water cooling, heat pipes, and/or other types of heat transfer fluids.

The efficiency vs. temperature performance has been determined theoretically and validated experimentally for many common semi conductor photovoltaic materials. In the case of silicon-based and the triple junction-based one-sun photocells, the constants are:

ΔE_{Silicon}=−0.0032%/° C. of the efficiency at 25° C.
and
ΔE_{TripleJunction}=−0.0062% of the efficiency at 25° C.

The conversion efficiencies at the cell level and system level can be further improved to reach 55% and 40%, respectively, by optimizing the cell design for the correct laser frequency, incorporating an efficient and intelligent power electronics system, and improving the packing density of the cells on the receiver surface to maximize the utilization of the incident optical energy.

The above description merely provides a disclosure of particular embodiments of the invention and is not intended for the purposes of limiting the same thereto. As such, the invention is not limited to only the above-described embodiments. Rather, it is recognized that one skilled in the art could conceive alternative embodiments that fall within the scope of the invention.

We claim:

1. A system that facilitates laser power beaming, comprising:
a receiver mounted to a vehicle and electrically coupled thereto;
an array of vertical multi-junction (VMJ) photocells, positioned on the receiver to receive a laser beam;
a global positioning system onboard the vehicle, which transmits location information;
a remote position tracking system that receives the location information from the global positioning system; and
a high-intensity laser that receives targeting information from the position tracking system, targets the receiver on the vehicle, and provides a laser beam pulse thereto;
wherein the VMJ photocells convert at least a portion of the received laser beam energy to electrical energy for use by the vehicle.

2. The system according to claim 1, wherein the vehicle further comprises a thermal sensor that sends a shut-off signal to the laser source when the thermal sensor registers a temperature at or above a predetermined acceptable temperature.

3. The system according to claim 1, wherein the receiver is coupled to a heat exchanger that dissipates heat away from the receiver.

4. The system according to claim 3, wherein the vehicle comprises a propeller and the heat exchanger is mounted to the vehicle at a location in the path of the propeller wash.

5. The system according to claim 1, wherein the vehicle is an unmanned aerial vehicle (UAV).

6. The system according to claim 1, wherein the laser source emits a near infra-red (IR) laser beam with a wavelength of approximately 750-1400 nm.

7. The system according to claim 6, wherein the laser source has a power output of approximately 30 kW to approximately 100 kW.

8. The system according to claim 6, wherein the laser source has a power output of approximately 1 kW to approximately 30 kW.

9. The system according to claim 6, wherein the laser source has a power output of approximately 50 W to approximately 1 kW.

10. The system according to claim 1, wherein the laser source emits a near infra-red (IR) laser beam with a wavelength of approximately 900-1100 nm.

11. The system according to claim 10, wherein the laser source has a power output of approximately 30 kW to approximately 100 kW.

12. The system according to claim 10, wherein the laser source has a power output of approximately 1 kW to approximately 30 kW.

13. The system according to claim 10, wherein the laser source has a power output of approximately 50 W to approximately 1 kW.

14. The system according to claim 1, wherein the laser source has a power output of approximately 30 kW to approximately 100 kW.

15. The system according to claim 1, wherein the laser source has a power output of approximately 1 kW to approximately 30 kW.

16. The system according to claim 1, wherein the laser source has a power output of approximately 50 W to approximately 1 kW.

17. A method of mid-air refueling of a vehicle using a near-infrared laser, comprising:
receiving location coordinate information from the vehicle;
targeting a receiver on the vehicle with a near-infrared laser source;
directing a laser beam form the laser source to a laser-receiving array on the receiver;
receiving the laser beam at one or more vertical multi-junction (VMJ) photocells in the laser-receiving array;
converting received laser energy into electrical energy;
storing the electrical energy in the VMJ photocells for use by the vehicle; and
dissipating heat caused by unconverted laser energy into the ambient atmosphere.

18. The method according to claim 17, wherein the laser source has a power output of approximately 1-100 kW, and wherein the VMJ photo cells convert at least approximately 50% of the received laser energy into electrical energy.

19. An apparatus for laser power beaming to refuel a vehicle, comprising:
means for receiving a high-intensity laser beam at the vehicle;
means for transmitting location information describing the coordinates of the vehicle;
means for receiving the location information;
means for aiming the high-intensity laser beam at the vehicle;
means for emitting the high-intensity laser beam targeted at the means for receiving the laser beam;
means for converting at least a portion of the received high-intensity laser beam energy to electrical energy for use by the vehicle; and
means for dissipating heat caused by high-intensity laser beam energy that is not converted into electrical energy.
